(19) United States
(12) Patent Application Publication
(10) Pub. No.: US 2012/0285370 A1
(43) Pub. Date: Nov. 15, 2012

(54) SUBLIMATION GROWTH OF SIC SINGLE CRYSTALS

(75) Inventors: Avinash K. Gupta, Basking Ridge, NJ (US); Ilya Zwieback, Washington Township, NJ (US); Edward Semenas, Allentown, PA (US); Varatharajan Rengarajan, Pine Brook, NJ (US); Marcus L. Getkin, Flanders, NJ (US)

(73) Assignee: II-VI INCORPORATED, Saxonburg, PA (US)

(21) Appl. No.: 13/394,982

(22) PCT Filed: Sep. 14, 2010
(86) PCT No.: PCT/US10/48765

§ 371 Date: Mar. 8, 2012

(30) Foreign Application Priority Data
Sep. 15, 2009 (US) 61242549

(51) Int. Cl. C30B 23/02

(52) U.S. Cl. 117/84; 118/726

(57) ABSTRACT

In SiC sublimation crystal growth, a crucible is charged with SiC source material and SiC seed crystal in spaced relation and a baffle is disposed in the growth crucible around the seed crystal. A first side of the baffle in the growth crucible defines a growth zone where a SiC single crystal grows on the SiC seed crystal. A second side of the baffle in the growth crucible defines a vapor-capture trap around the SiC seed crystal. The growth crucible is heated to a SiC growth temperature whereupon the SiC source material sublimates and forms a vapor which is transported to the growth zone where the SiC crystal grows by precipitation of the vapor on the SiC seed crystal. A fraction of this vapor enters the vapor-capture trap where it is removed from the growth zone during growth of the SiC crystal.

### BACKGROUND OF THE INVENTION

1. Field of the Invention

The present invention relates to Physical Vapor Transport growth of SiC single crystals.

2. Description of Related Art

Wafers of silicon carbide of the 4H and 6H polytype serve as lattice-matched substrates to grow epitaxial layers of SiC and GaN, which are used for fabrication of SiC- and GaN-based semiconductor devices for power and RF applications.

Large, industrial-size SiC single crystals are grown by a sublimation technique commonly known as Physical Vapor Transport (PVT). PVT growth is usually carried out in a graphite crucible that includes solid SiC sublimation source material disposed, typically, at the crucible bottom and a SiC single crystal seed disposed, typically, at the crucible top. The sublimation source material is, usually, polycrystalline SiC grain synthesized separately. The loaded crucible is placed in a furnace and heated to the growth temperature, which is, generally, between 2000° C. and 2400° C. During growth, the source material temperature is maintained higher than that of the seed crystal, typically, by 10° to 200°.

Upon reaching a suitable high temperature, the sublimation source vaporizes and fills the interior of the crucible with vapor species, such as Si, Si₂C and/or SiC₂. The temperature difference between the sublimation source and the seed crystal forces the vapor species to migrate and condense on the seed crystal causing a SiC single crystal to grow on the seed crystal. In order to control the growth rate and thus facilitate good crystal quality, PVT growth is carried out under a small pressure of inert gas, typically, between 1 and 100 Torr.

Generally, SiC crystals grown using this basic PVT arrangement suffer from structural defects, such as inclusions, micropipes and dislocations. It is commonly believed that inclusions of carbon, silicon and foreign polytypes are caused by deviations in the vapor phase stoichiometry, which is conventionally expressed as the Si:C atomic ratio. It is well-known that SiC sublimes incongruently with the Si:C atomic ratio in the vapor larger than 1 Depending on the SiC source conditions (such as the grain structure and size, polytype composition, stoichiometry, temperature, etc.) the Si:C ratio in the vapor over the sublimation source material can be as high as 1.5 or even higher. When the Si:C ratio in the vapor is too high, silicon inclusions form in the growing SiC crystal. Conversely, when the Si:C atomic ratio in the vapor is too low, carbon inclusions form in the growing SiC crystal.

It is also believed that stable growth of SiC single crystals of hexagonal 4H and 6H polytypes requires a carbon-rich vapor phase, whereas inclusions of foreign polytypes such as 15R are caused by deviations in the vapor stoichiometry.

Inclusions of metal carbides can appear in grown SiC single crystals when the SiC sublimation source material contains metallic contaminants.

Inclusions in a PVT grown SiC single crystal leads to local stress, which is relieved via generation, multiplication and movement of dislocations and micropipes. When SiC single crystal wafers are used as substrates in GaN or SiC epitaxy, the presence of inclusions, micropipes and dislocations in the substrate is harmful to the quality of the epilayers and the performance of semiconductor devices formed on said epilayers.

Since the inception of the PVT growth technique, a number of process modifications have been developed with the aim to improve the grown crystal quality and reduce defect densities.

For example, U.S. Pat. No. 5,858,086 to Hunter (hereinafter “the '086 patent”) discloses a system for the growth of AlN (aluminum nitride) crystals by sublimation. A schematic diagram of the system disclosed in the '086 Hunter patent is shown in FIG. 1, wherein vapor 2 from AlN source material 4 enters a space 6 in front of an AlN seed crystal 8 and precipitates on said seed crystal 8 causing an AlN crystal 10 to grow. As the growth of AlN crystal 10 progresses, vapor 2 surrounding the growing crystal 10 becomes stagnant, contaminated and generally unsuitable for the growth of a high-quality AlN crystal 10. In order to avoid this deficiency, a perforated baffle 12 is placed around AlN seed crystal 8 and the space where AlN crystal 10 is to grow. As shown in FIG. 1, baffle 12 extends toward AlN source 4. The portion of growth crucible 14 surrounding baffle 12 is configured to define therewith a gap 16 that enables a portion of vapor 2, shown by arrows 18, that passes through perforated baffle 12 to escape from inside growth crucible 14 to a space outside growth crucible 14 via one or more holes of vents 19.

U.S. Pat. No. 5,985,024 to Balakrishna et al. discloses a system for the growth of high-purity SiC single crystals. A schematic diagram of the system disclosed in the Balakrishna et al. patent is shown in FIG. 2, wherein silicon vapor 20 from Si sublimation source material 22 rises toward a SiC seed crystal 24 where it mixes with carbon-containing gas 26 supplied from an external source. The SiC vapor 28 produced as a result of reaction between Si- and C-containing vapors reaches SiC seed crystal 24, precipitates on it and causes a SiC crystal 30 to grow on SiC seed crystal 24. Spent SiC vapors 28, gases and gaseous contaminants escape from inside growth crucible 32 to a space outside growth crucible 32 via a gap 34 between SiC crystal 30 and a protective liner 36, desirably made from high purity silicon carbide or tantalum carbide, and one or more holes or vents 38 at the top of growth crucible 32. A porous graphite wall 40 desirably supports protective liner 36 at an appropriate position within growth crucible 32.

U.S. Pat. No. 6,045,613 to Hunter (hereinafter “the '613 patent”) discloses the SiC crystal growth system shown in FIG. 3, wherein Si vapors 48 from Si sublimation source material 50 along with C or N gas 52 rise toward a SiC or SiN single crystal seed 54 where they form a growing SiC or SiN crystal 56, respectively. (The growth system shown in FIG. 3 can also be utilized to grow MN crystals.) Similar to the '086 patent (FIG. 1), spent or contaminated gases and vapors 48, 52 escape growth crucible 59 through one or more vents or holes 58 provided at the top of growth crucible 59. Once outside growth crucible 59, the escaped vapors 48, 52 are disposed of in a special gettering furnace external to the growth crucible (not shown).

U.S. Pat. No. 6,086,672 to Hunter discloses a system for the growth of AlN—SiC alloy crystals that is similar to the growth system disclosed in the '086 Hunter patent (FIG. 1) described above.

U.S. Pat. No. 7,323,052 to Tsvetkov et al. discloses sublimation growth of SiC single crystals containing reduced densities of point defects. The cause of such defects is believed to be vapor species that contain too much silicon. A schematic diagram of the apparatus disclosed in this patent is shown in FIG. 4, wherein a graphite growth crucible 60 defines a sublimation chamber 62 with SiC sublimation source material 64 at the bottom of chamber 62 and a SiC crystal seed 66 disposed on a holder 68 at the top of chamber 62. In order to optimize vapor stoichiometry during the growth of a SiC crystal 70 on seed crystal 66, a fraction of the SiC vapor 74 is vented from inside growth crucible 60 to a chamber or space 76 outside of growth crucible 60 via one or more outlets 72 at the top of growth crucible 60. Chamber 76 is defined between the exterior of growth crucible 60 and an interior of an outer wall 78 of the furnace chamber. A suitable insulation 80 typically resides in chamber 76.

Generally, crucibles made of high-density, small-grain graphite are utilized in SiC sublimation crystal growth. Herein, high-density or dense graphite is graphite having a density between 1.70 and 1.85 g/cm³, grain sizes between several and tens of microns, and porosity on the order of 10%. Those skilled in the art recognize that such graphite is highly permeable to common gases, such as N₂, Ar, He, CO, CO₂, HCl, etc. However, dense graphite shows very low permeability to the vapors formed as a result of SiC sublimation: Si, Si₂C and SiC₂. Vapor losses from an enclosed crucible made of dense graphite incurred during SiC sublimation growth, typically, do not exceed several grams, and this is not enough to provide for sufficient or desirable removal of the vapor from the crucible. This low permeability of dense graphite to the Si-bearing vapors is the main reason why special holes or vents are made in the growth crucibles of the prior art discussed above for the purpose of venting.

It is also known that low-density, porous graphite can show higher permeability to the Si-containing vapor species formed as a result of SiC sublimation. Herein, low-density graphite is graphite having a density between 0.8 and 1.6 g/cm³; a porosity between 30% and 60%; and pore sizes between 1 and 100 microns. These properties of low-density graphite are utilized in U.S. Pat. No. 7,323,052 to Tsvetkov et al., where, alternatively to outlets 72 shown in FIG. 4, one or more sections of growth crucible 60 can be made of lower-density graphite permeable to atomic silicon vapor in particular. Atomic Si escapes from inside growth crucible 60 by diffusing through said lower-density graphite into chamber 76, thus reducing the Si content of vapor 74 in the zone of chamber 62 where SiC crystal 70 grows.

In summary, the aforementioned prior art teaches partial removal of vapor from the space surrounding the growing crystal by way of venting said vapor from inside the growth crucible to a space outside the growth crucible, e.g., into a chamber or space formed between the growth crucible and the outer wall of the furnace chamber where thermal insulation typically resides.

Venting the vapor into this chamber, however, has its problems. Specifically, the chamber or space surrounding the growth crucible is usually filled with thermal insulation made of purified, light-weight, fibrous graphite. The Si-containing vapor is very reactive toward graphite, especially when graphite is in such a light-weight form. Degradation of the thermal insulation caused by vapor erosion leads to uncontrollable changes in the temperatures of the crucible and, hence, the source and crystal. This has a negative effect on the growth process and crystal quality.

Another consequence of the escape of vapor into the chamber from the crucible is a reduced service time of the expensive thermal insulation. Utilization of a special gettering furnace for the disposal of the escaping vapor, as taught in the '613 patent, adds to the complexity and cost of the growth system.

### SUMMARY OF THE INVENTION

The present invention is an improved SiC sublimation crystal growth process and apparatus for the growth of high quality SiC single crystals suitable for the fabrication of industrial size substrates, including substrates of 2″, 3″, 100 mm, 125 mm and 150 mm in diameter. The crystal growth crucible includes grains of SiC source material and a SiC seed crystal disposed inside a sealed graphite crucible in spaced relationship. During growth, the SiC source material vaporizes producing volatile vapor species, such as Si, Si₂C and SiC₂. Driven by a temperature gradient inside of the crucible, these vapor species migrate toward the seed crystal and precipitate on it causing the growth of a SiC single crystal on the seed crystal.

The SiC crystal growth crucible includes a baffle disposed around the seed crystal in the growth crucible, said baffle defining on a first side thereof in said growth crucible a growth zone where the SiC single crystal grows on the seed crystal, said baffle defining on a second side thereof in said growth crucible a vapor-capture trap around the seed crystal. The vapor-capture trap can be located at a position in the growth crucible where the temperature is lower than that of the seed crystal during the growth of the SiC single crystal on the seed crystal. The temperature within the vapor-capture trap can be lower than the temperature of the seed crystal by 3° C. to 20° C. The crucible design includes a pathway that enables the vapor to migrate toward the vapor-capture trap and enter it.

Upon reaching the vapor-capture trap, the Si-bearing vapor becomes supercooled and precipitates forming solid deposits of polycrystalline SiC within the vapor-capture trap. As a result of this process, part of the vapor is removed from the vicinity of the growing SiC single crystal, i.e., vapor is removed from the vicinity of the SiC single crystal growth interface. Simultaneously, unwanted vapor constituents harmful to the crystal quality are also removed. These harmful components include excessive silicon- or carbon-containing vapors as well as volatile contaminants.

The SiC crystal growth crucible can further include a porous vapor-absorbing member disposed in the vapor-capture trap and operative for absorbing vapor produced during sublimation growth of the SiC single crystal on the seed crystal.

The porous vapor-absorbing member can be disposed in the vapor-capture trap at a position where the vapor-absorbing member is at a temperature lower than that of the seed crystal during the growth of the SiC single crystal on the seed crystal. The temperature of the vapor-absorbing member during the growth of the SiC single crystal on the seed crystal can be lower than the temperature of the seed crystal by 3° C. to 20° C. The crucible design desirably includes a pathway that enables the vapor to migrate toward the porous vapor-absorbing member, permeate it, and react with it.

Upon reaching the vapor-absorbing member, the vapor permeates the pores of the vapor-absorbing member where it chemically reacts with the material of the member to form solid products. As a result of this process, part of the vapor is removed from the vicinity of the growing SiC single crystal. Simultaneously, unwanted vapor constituents harmful to the crystal quality are also removed. These harmful components include excessive silicon- or carbon-containing vapors as well as volatile contaminants.

In one embodiment, the vapor-absorbing member is made of purified porous graphite having a density, desirably, between 0.8 and 1.6 g/cm³; a porosity, desirably, between 30% and 60%; and pore sizes, desirably, between 1 and 100 microns.

The use of the vapor-absorbing member inside of the growth crucible facilitates growth of SiC single crystal boules with reduced densities of defects such as inclusions, micropipes and dislocations.

More specifically, the invention is an apparatus for sublimation growth of a SiC single crystal that includes a growth crucible operative for receiving a source material and a seed crystal in spaced relation and for substantially preventing the escape of vapor produced during sublimation growth of a SiC single crystal on the seed crystal from inside said growth crucible; and a baffle disposed around the seed crystal in the growth crucible, said baffle defining on a first side thereof in said growth crucible a growth zone where the SiC single crystal grows on the seed crystal, said baffle defining on a second side thereof in said growth crucible a vapor capture space, hereinafter a “vapor-capture trap”, around the seed crystal.

For substantially preventing the escape of vapor produced during sublimation growth of a SiC single crystal on the seed crystal, said growth crucible: can be made from a material that is substantially impermeable to the passage of the vapor produced during sublimation growth of a SiC single crystal on the seed crystal; and can include no intentional pathways or holes for escape of the vapor produced during sublimation growth of a SiC single crystal on the seed crystal from inside the growth crucible to outside the growth crucible.

The vapor-capture trap can be located at a position in the growth crucible where the temperature is lower than that of the seed crystal during the growth of the SiC single crystal on the seed crystal.

The apparatus can further include a vapor-absorbing member disposed in the vapor-capture trap and operative for absorbing vapor produced during sublimation growth of the SiC single crystal on the seed crystal.

The vapor-absorbing member can be disposed in the vapor-capture trap at a position where the vapor-absorbing member is at a temperature lower than that of the seed crystal during the growth of the SiC single crystal on the seed crystal.

The temperature of the vapor-absorbing member during the growth of the SiC single crystal on the seed crystal can be lower than the temperature of the seed crystal by 3° C. to 20° C.

The vapor-absorbing member can be made from porous graphite having a density between 0.8 and 1.6 g/cm³; a porosity between 30% and 60%; and pore sizes between 1 and 100 microns.

The baffle can define a pathway inside said growth crucible for the vapor to flow into the vapor-capture trap.

The growth crucible can include therein a pedestal for supporting the seed crystal intermediate a top of the growth crucible and the source material. The pedestal can have a height between 5 mm and 25 mm. The pathway can comprise a gap between an inner diameter of the baffle and an outer diameter of the pedestal. The gap can be between 1 mm and 8 mm wide. The pathway can comprise one or more holes in the baffle.

The invention is also a method of SiC sublimation crystal growth comprising: (a) providing a growth crucible charged with a source material and a seed crystal in spaced relation and a baffle disposed in the growth crucible around the seed crystal, said baffle defining on a first side thereof a growth zone where a single crystal grows on the seed crystal, said baffle defining on a second side thereof a vapor-capture trap around the seed crystal; and (b) heating the growth crucible of step (a) to a growth temperature whereupon a temperature gradient forms in the growth chamber that causes the source material to sublimate and form a vapor which is transported by the temperature gradient to the growth zone of the growth crucible where the single crystal grows by precipitation of the vapor on the seed crystal, wherein a fraction of the vapor enters the vapor-capture trap.

The vapor entering the vapor-capture trap can be removed during growth of the crystal from the growth zone by forming a deposit therein. One or more of the source material, the seed crystal, and the single crystal can be SiC.

The vapor-capture trap can be located at a position in the growth crucible where the temperature is lower than that of the seed crystal during the growth of the single crystal on the seed crystal.

A vapor-absorbing member can be disposed inside the vapor-capture trap. The vapor entering the vapor-capture trap can be removed during growth of the crystal from the growth zone by chemically reacting with the vapor-absorbing member, e.g., without limitation, to form a deposit.

The vapor-absorbing member can be at a lower temperature than the seed crystal during growth of the single crystal.

The vapor-absorbing member can be made from porous graphite with a density between 0.8 and 1.6 g/cm³; a porosity between 30% and 60%; and pore sizes between 1 and 100 microns.

The weight of the deposit formed in the vapor-capture trap can be between 5% and 20% of the weight of the grown crystal. Stated differently, the weight of the vapor absorbed by the vapor-absorbing member can be between 5% and 20% of the weight of the grown crystal.

The baffle can define a pathway for the vapor to flow to the vapor-capture trap. The growth crucible of step (a) can further include a pedestal for supporting the seed crystal intermediate a top of the growth crucible and the source material. The pathway can comprise a gap formed between an inner diameter of the baffle and an outer diameter of the pedestal.

The pathway can comprise at least one perforation in a wall of the baffle.

### BRIEF DESCRIPTION OF THE DRAWINGS

FIGS. 1-4 are prior art systems for the growth of crystals by sublimation; and

FIGS. 5-7 are systems in accordance with the present invention for the growth of crystals, especially SiC crystals, by sublimation.

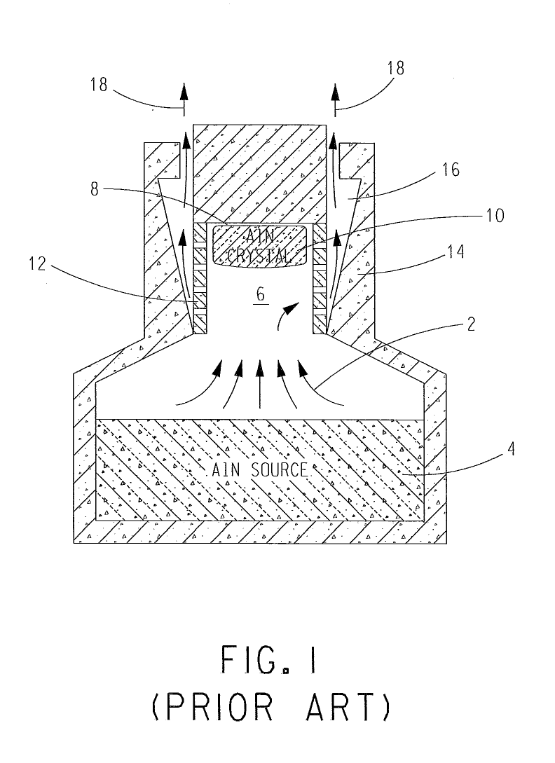

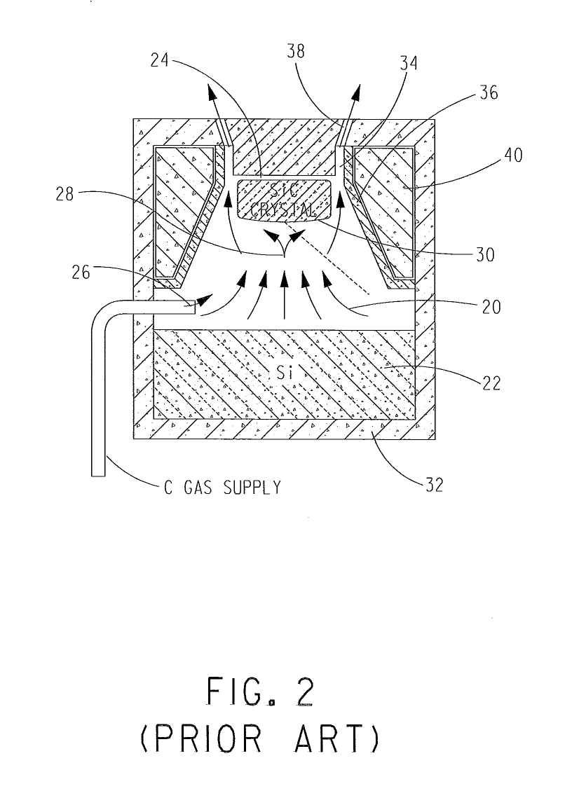

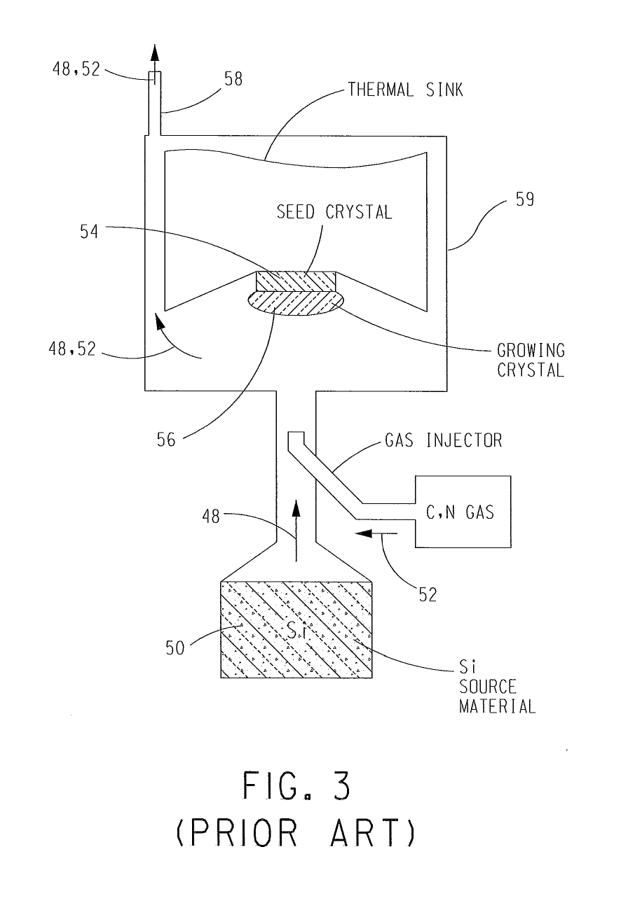

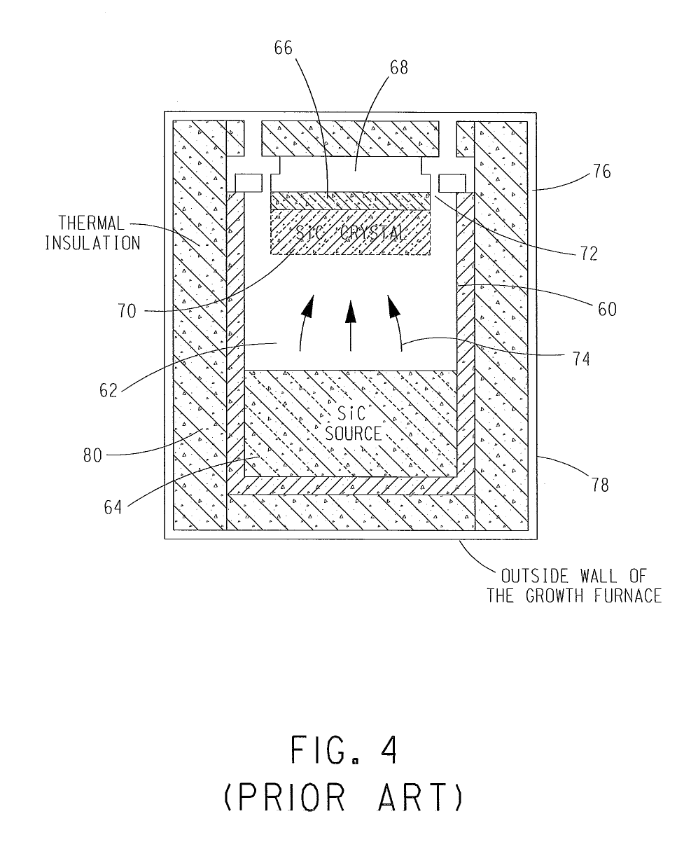

### DETAILED DESCRIPTION OF THE INVENTION

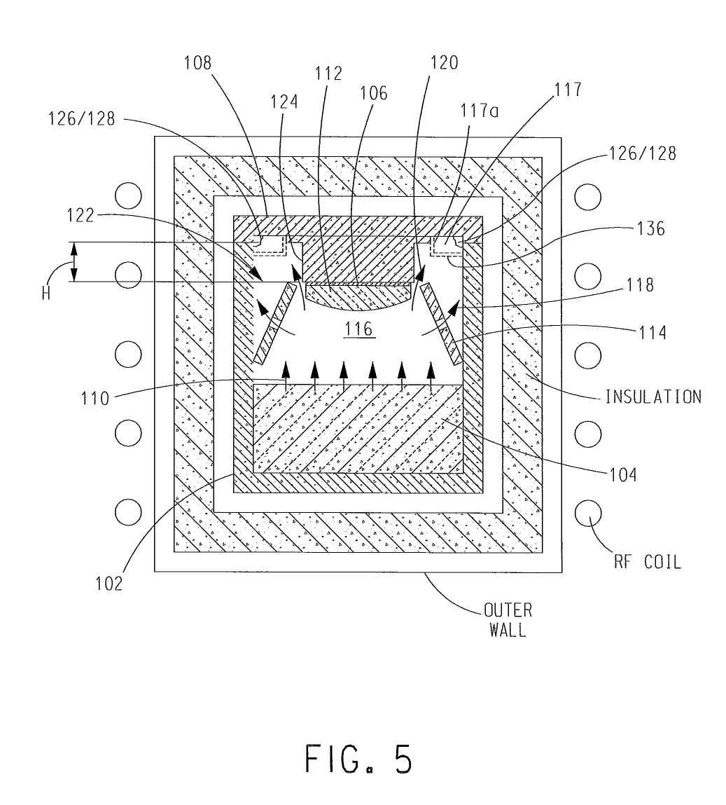

The present invention will now be described with reference to FIGS. 5-7 where like reference numbers correspond to like elements.

With reference to FIG. 5, PVT growth of a SiC crystal, desirably a SiC single crystal, is carried out in a graphite crucible 102 that includes grains of SiC source material 104 and a SiC seed crystal 106 in spaced relationship. Desirably, source material 104 is disposed at the bottom of crucible 102 and seed crystal 106 at the top of crucible 102, e.g., seed crystal 106 is attached to a lid 108 of crucible 102. Upon reaching a desired sublimation growth temperature, SiC source material 104 sublimes and fills the interior of crucible 102 with Si-rich vapor species 110, such as Si, Si₂C and SiC₂ volatile molecular species.

Driven by a vertical temperature gradient inside of crucible 102, vapor 110 migrates in the axial direction toward seed crystal 106 and condenses on seed crystal 106 causing growth of a SiC single crystal 112 thereon. The growing SiC crystal 112 is surrounded by a baffle 114 which delimits a space 116 adjacent growing SiC crystal 112. Space 116 is also known as the “growth zone”. During growth, growth zone 116 fills with volatile byproducts emerging as a result of vapor condensation, crystal growth and graphite erosion. These volatile byproducts can contain impurities as well as excessive silicon or carbon. Such uncontrollable changes in the vapor phase composition in growth zone 116 affect negatively the quality of growing SiC crystal 112.

Desirably, crucible 102 is formed from high density graphite that “substantially prevents” the escape of vapor 110 from the inside crucible 102. To “substantially prevent” the escape of vapor 110 from the interior of crucible 102, the high density graphite forming crucible 102 is “substantially impermeable” to vapors 110 and crucible 102 includes no intentional holes or vents for the escape of vapor 110 from the interior of crucible 102. Herein, crucible 102 “substantially preventing” the escape of vapor 110 from the interior thereof and crucible 102 being made from high density graphite that is “substantially impermeable” to vapors 110 means that the loss of vapor 110 from the interior of crucible 102 during the growth of SiC single crystal 112 on seed crystal 106 occurs via diffusion of vapor 110 across the wall of crucible 102 and lid 108, and the total of such loss of vapor 110 from the interior of crucible 102 during the growth of SiC single crystal 112 on seed crystal 106 is between 1% and 5% of the initial weight of SiC source material 104.

A vapor-capture trap 117 is provided in the interior of the crucible 102 in order to reduce the aforementioned uncontrollable changes in the vapor phase composition in the growth zone. The thermal field in the crucible is tuned such that vapor-capture trap 117 has the lowest temperature in the crucible interior. In particular, the temperature in vapor-capture trap 117 is desirably lower than the temperature of the seed 106. A common approach to tuning the temperature field inside the SiC growth crucible is by using finite-element thermal modeling. Driven by the temperature and pressure gradients, vapor 110 migrates toward the crucible top, reaches vapor-capture trap 117, and precipitates in vapor-capture trap 117 forming a solid polycrystalline SiC deposit 126 in vapor-capture trap 117, e.g., without limitation, on the interior surface of the wall of crucible 102 adjacent lid 108 and, optionally, on the interior surface of lid 108 adjacent the wall of crucible 102. As a result of the formation of solid polycrystalline SiC deposit 126, a fraction of vapor 110 is removed from growth zone 116. The shape of vapor-capture trap 117 in FIG. 5 is shown for the purpose of illustration only, and it is not to be construed as limiting the invention, as this space can have any suitable and/or desirable shape.

A vapor-capture member 117a (shown in phantom in FIG. 5) made of vapor-absorbing, porous material can optionally be placed inside crucible 102, desirably in vapor-capture trap 117, in order to assist in the reduction of uncontrollable changes in the vapor phase composition in growth zone 116. The vapor 110 upon reaching member 117a permeates its pores and chemically reacts with the material of member 117a leading to the formation of solid polycrystalline SiC deposit 128 on or in member 117a.

Two possible vapor flows from growth zone 116 toward vapor-capture trap 117 and, if provided, member 117a are shown in FIG. 5 by arrows 118 and 120. Arrow 118 shows the flow of vapor across baffle 114, for instance, through one or more perforations in baffle 114. Arrow 120 shows the flow of vapor around baffle 114, for instance, through a gap 122 defined between baffle 114 and seed crystal 106, growing crystal 112, and/or a seed pedestal 124 upon which seed crystal 106 is mounted. Baffle 114 is shown in FIG. 5 as having a cone shape with the narrow opening of the cone defining with seed crystal 106 and growing crystal 112, the gap 122, and with the wide opening of the cone facing source material 104. However, the illustration of baffle 114 as having a cone shape is not to be construed as limiting the invention as it is envisioned that baffle 114 can have any suitable and/or desirable shape.

Desirably, vapor-absorbing member 117a is made of purified porous graphite having a density, desirably, between 0.8 and 1.6 g/cm³; a porosity, desirably, between 30% and 60%; and pore sizes, desirably, between 1 and 100 microns, i.e., a low-density graphite. Chemical reaction between vapor 110 and the carbon of the member 117a leads to the formation of solid polycrystalline SiC deposit 128 on or inside the pores of the member 117a. As a result of this reaction and the formation of the SiC deposits 128, a fraction of vapor 110 is removed from growth zone 116. Simultaneously, excessive silicon- or carbon-containing vapors, as well as volatile contaminants, are also removed from growth zone 116.

With continuing reference to FIG. 5, vapor-capture trap 117 can comprise all or part of the space generally bounded by the side of baffle 114 that faces away from growth zone 116, the portion of lid 108 above baffle 144, and the portion of the interior wall of crucible 102 between lid 108 and the lower end of baffle 144. If provided, member 117a can be positioned at any suitable and/or desirable location within this space. Desirably, however, vapor-capture trap 117 is comprised of a space 136 (shown in phantom in FIG. 5) adjacent the upper outside portion of the interior of crucible 102. In FIG. 5, lid 108 and the interior wall of crucible 102 adjacent lid 108 define two boundaries of space 136. However, this is not to be construed as limiting the invention. If provided, member 117a is desirably positioned at any suitable and/or desirable location within space 136, as shown in phantom in FIG. 5.

Two extremes are desirably avoided in order for vapor-capture trap 117 and, if provided, vapor-absorbing member 117a in vapor-capture trap 117 to be beneficial to the growth of SiC crystal 112 and the quality of the grown SiC crystal 112. In one extreme, too much of vapor 110 is removed from growth zone 116, leading to a dramatic reduction in the growth rate of SiC crystal 112. Another extreme is when too little vapor 110 is removed from growth zone 116, whereupon the presence of the vapor-capture trap 117 and, if provided, vapor-absorbing member 117a in crucible 102 has no beneficial effect on the quality of the grown SiC crystal 112.

Experimental results show that in order to realize the beneficial effects of vapor-capture trap 117 and, if provided, vapor-absorbing member 117a in vapor-capture trap 117, the weight of SiC deposit 126 or 128 formed in vapor-capture trap 117 or, if provided, vapor-absorbing member 117a, respectively, is desirably between 5% and 20% of the weight of the grown SiC single crystal 112. For example, where only vapor-capture trap 117 is present (i.e., without vapor-absorbing member 117a in vapor-capture trap 117), the weight of SiC deposit 126 formed in vapor-capture trap 117 is desirably between 5% and 20% of the weight of the grown SiC single crystal 112. On the other hand, where vapor-absorbing member 117a is included in vapor-capture trap 117, the weight of SiC deposit 128 formed in vapor-absorbing member 117a is desirably between 5% and 20% of the weight of the grown SiC single crystal 112.

It is envisioned, that when vapor-absorbing member 117a is included in vapor-capture trap 117, that some SiC deposit 126 may also form on the wall of crucible 102, the interior of lid 108, or both, adjacent space 136. However, it is envisioned that the total of SiC deposits 126 and 128 will desirably be between 5% and 20% of the weight of the grown SiC single crystal 112.

Desirably, control over the amount of vapor 110 absorbed in vapor-capture trap 117 and, if provided, vapor-absorbing member 117a in vapor-capture trap 117 is achieved by controlling the temperature of vapor-capture trap 117 and, if provided, vapor-absorbing member 117a in vapor-capture trap 117, and by providing a pathway 118 and/or 120 of desired cross-section, length and geometry for vapor 110 to flow from growth zone 116 to vapor-capture trap 117 and, if provided, vapor-absorbing member 117a in vapor-capture trap 117.

In order for the SiC deposit to form reliably inside vapor-capture trap 117 and, if provided, vapor-absorbing member 117a in vapor-capture trap 117, the temperature of vapor-capture trap 117 and, if provided, vapor-absorbing member 117a in vapor-capture trap 117 is desirably the lowest inside of crucible 102 during the growth of SiC crystal 112. More specifically, the temperature of vapor-capture trap 117 and, if provided, vapor-absorbing member 117a in vapor-capture trap 117 is desirably lower than that of seed crystal 106. In one embodiment, the temperature of vapor-capture trap 117 and, if provided, vapor-absorbing member 117a in vapor-capture trap 117 is lower than that of seed crystal 106, desirably, by 3° C. to 20° C.

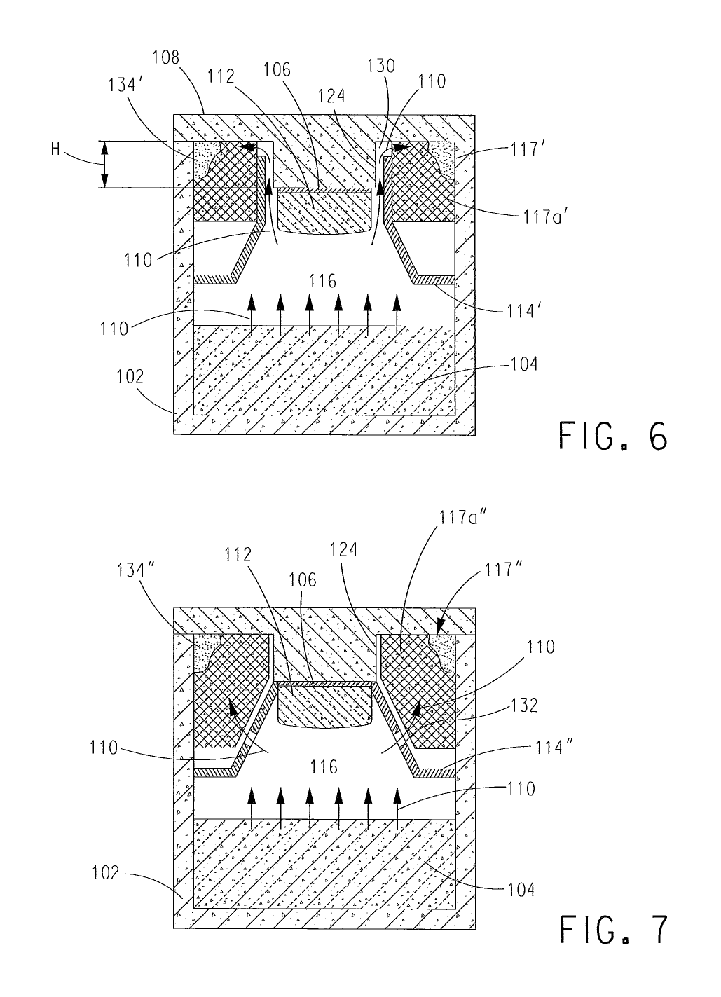

This difference between the temperatures of seed crystal 106 and vapor-capture trap 117 and, if provided, vapor-absorbing member 117a in vapor-capture trap 117 can be realized in a number of ways. In one embodiment, the desired temperature difference between seed 106 and vapor-absorbing member 117a in vapor-capture trap 117 is achieved by the following combination: (i) vapor-absorbing member 117a (included in vapor-capture trap 117) is shaped as a short cylinder, as shown in FIG. 6, as a truncated cone, or as a combination thereof, as shown in FIG. 7; (ii) vapor-absorbing member 117a is disposed in the upper extreme, e.g., at or adjacent the upper end or top of crucible 102; (iii) seed crystal 106 is disposed on pedestal 124, as shown in FIG. 5, whereupon seed crystal 106 is disposed inside crucible 102 away from the top or lid 108 of crucible 102; and (iv) the height H of the pedestal 124 is, desirably, between 5 and 25 mm.

The geometry of the vapor pathway(s) that vapor 110 traverses to reach vapor-capture trap 117 and, if provided, vapor-absorbing member 117a in vapor-capture trap 117, specifically the length and cross-section of such vapor pathway(s), is another factor that can be used to control the amount of removed vapor 110. Two exemplary vapor pathways are shown schematically in FIGS. 6 and 7. These two vapor pathways do not produce deleterious effects on the quality of the growing SiC crystal 112 and can be easily implemented.

In FIG. 6, crucible 102 includes a baffle 114′ made of dense graphite that surrounds at least the lower part of pedestal 124, seed crystal 106, and the space where SiC crystal 112 grows. An annular gap 130 exists between baffle 114′ and pedestal 124. Gap 130 forms a pathway for vapor 110 to flow to a vapor-capture trap 117′ and, if provided, a vapor-absorbing member 117a′ in vapor-capture trap 117′. In FIG. 7, baffle 114″ surrounding seed crystal 106 and the space where SiC crystal 112 grows is perforated. That is, baffle 114″ includes a plurality of openings 132 that form pathway(s) for vapor 110 to flow to vapor-capture trap 117″ and, if provided, vapor-absorbing member 117a″ in vapor-capture trap 117″.

Upon reaching vapor-absorbing member 117a′ disposed in vapor-capture trap 117′, vapor 110 permeates it, diffuses through its bulk and reacts with the carbon forming said member 117a′. As a result of such reaction, polycrystalline SiC deposit 134′ forms on the member 117a′ and/or inside said member 117a′ in its coldest spot. It is envisioned that a portion of SiC deposit 134′ may also form on the wall of vapor-capture trap 117′.

Smartly, upon reaching vapor-absorbing member 117a″ in vapor-capture trap 117″, vapor 110 permeates it, diffuses through its bulk and reacts with the carbon forming said member 117a″. As a result of such reaction, polycrystalline SiC deposit 134″ forms on the member 117a″ and/or inside said member 117a″ in its coldest spot. It is envisioned that a portion of SiC deposit 134″ may also form on the wall of vapor-capture trap 117″.

When vapor-capture trap 117′ in FIG. 6 does not include vapor-absorbing member 117a′, SiC deposit 134′ will form on the wall(s) of vapor-capture trap 117′ in its coldest spot. Similarly, when vapor-capture trap 117″ in FIG. 7 does not include vapor-absorbing member 117a″, SiC deposit 134″ will form on the wall(s) of vapor-capture trap 117″ in its coldest spot.

### Example 1

### Growth of 3″ Diameter Semi-Insulating 6H SiC Crystal

This growth run was carried out in a growth furnace having the crucible, baffle, and vapor-absorbing member 117a′ arrangement like the one shown in FIG. 6. In this growth run, a crystal growth crucible 102 made of dense, isostatically molded graphite was prepared and purified by high-temperature treatment in a halogen-containing atmosphere. High-purity SiC sublimation source material 104, i.e., SiC grains 0.5 to 2 mm in size, was synthesized prior to growth of SiC crystal 112 in a separate synthesis process. A charge of 600 g of the SiC source material 104 was disposed at the bottom of crucible 102 and served during growth of SiC crystal 112 as the solid sublimation source. In order to produce semi-insulating SiC crystal 112, the source material 104 included vanadium as a compensating dopant. The amount of vanadium and other details of vanadium doping were in accordance with the prior art.

A 3.25″ diameter SiC wafer of the 6H polytype was used as the seed crystal 106. This wafer was oriented on-axis, with its faces parallel to the basal c-plane. The surface of the wafer where the growth of SiC crystal 112 was to occur was polished prior to the growth of SiC crystal 112 using a chemico-mechanical polishing (CMP) technique to remove scratches and sub-surface damage. This seed crystal 106 was attached to pedestal 124 of crucible lid 108 using a high-temperature carbon adhesive. Pedestal 124 had a height H of 12.5 mm.

Baffle 114′ was machined from dense, isostatically molded and halogen-purified graphite and had a 3 mm thick wall. The inner diameter of baffle 114′ was larger than the outer diameter of pedestal 124 to form a 2 mm wide annular gap 130 between pedestal 124 and baffle 114′.

Vapor-absorbing member 117a′, shaped as a cylinder in FIG. 6, was machined from halogen-purified porous graphite with a density of 1.0 g/cm³; a porosity of 50%; and pore sizes in the range of 20-80 microns. Vapor-absorbing member 117a′ was disposed in vapor-capture trap 117′ as shown in FIG. 640. [068] Crucible 102 was loaded into a water-cooled growth chamber of the growth furnace having an outer wall made of fused silica and an external RF coil that was utilized to inductively heat crucible 102, which acts as an RF susceptor, in a manner known in the art. Thermal insulation made of fibrous light-weight graphite foam was placed in the growth chamber around crucible 102. The interior of the growth furnace and, hence, the interior of crucible 102 were evacuated to a pressure of 1·10⁻⁶ Torr and flushed several times with 99.9999% pure argon to remove absorbed gases and moisture. Then, the interior of the growth furnace and, hence, the interior of crucible 102 was backfilled with Ar to 500 Torr and RF power was applied to the RF coil which inductively caused the temperature of crucible 102 to increase to about 2100° C. over a period of six hours. Because of the porosity of crucible 102 to gases, the gas pressure inside crucible 102 very quickly becomes the same as the gas pressure inside of the growth chamber.

Following this, the RF coil position and the RF power were adjusted to achieve a temperature of source material 104 of 2120° C. and a temperature of seed crystal 106 of 2090° C. The Ar pressure was then reduced to 10 Torr to start sublimation growth of SiC crystal 112 boule. Upon completion of the run, the growth furnace was cooled to room temperature over a period of 12 hours.

The grown 6H boule of SiC crystal 112 weighed 300 grams. The weight of the polycrystalline SiC deposit 134 formed inside vapor-absorbing member 117′ was about 20 grams. The grown boule of SiC crystal 112 contained neither carbon particles, nor Si droplets, nor foreign polytype inclusions. The micropipe density in this boule of SiC crystal 112 was about 0.9 cm⁻² and the dislocation density was close to 1·10⁴ cm⁻².

The boule of SiC crystal 112 was fabricated into 25 standard 3″ diameter, 400 micron thick wafers, and their resistivity was measured and mapped using Corema, a contactless resistivity tool. The resistivity of all wafers was close to 1·10¹¹ Ohm-cm, with a standard deviation below 10%.

### Example 2

### Growth of 100 mm Diameter Semi-Insulating 6H SiC Crystal

This growth run gas was carried out in a growth furnace having the crucible, baffle, and vapor-absorbing member 117a″ arrangement like the one shown in FIG. 7. The crystal growth crucible 102 was made of dense, isostatically molded and halogen-purified graphite. High-purity SiC grain source material 104, 0.5 to 2 mm in size, was synthesized prior to growth in a separate synthesis process. A charge of 900 g of the SiC grain source material 104 was disposed at the bottom of crucible 102 and served during growth of SiC crystal 112 as a solid sublimation source.

A 110 mm diameter SiC wafer of the 6H polytype oriented on-axis was used as the seed crystal 106. The surface of the wafer where SiC crystal 112 was to grow was CMP polished prior to growth. The seed crystal 106 was attached to pedestal 124 of crucible lid 108 using a high-temperature adhesive. Pedestal 124 had a height of 10 mm.

Baffle 114″ used in this run had the configuration shown in FIG. 7. The wall thickness of baffle 114″ was 3 mm. Baffle 114″ was perforated by drilling twenty-four 2 mm diameter holes in the wall of baffle 114″ in three rows of eight holes spaced uniformly around the circumference of baffle 114″. The number of perforations, however, can be between 4 and 40 and the diameter of each perforation can be between 1 and 3 mm.

Vapor-absorbing member 117″ had the configuration shown in FIG. 7, namely, a combination of cylinder (top) and truncated cone (bottom). Vapor-absorbing member 117″ was machined from halogen-purified porous graphite with a density of 1.0 g/cm³; a porosity of 50%; and pore sizes between 20 and 80 microns.

The growth conditions were as follows: the temperature of source material 104 was 2150° C.; the temperature of seed crystal 106 was 2100° C.; and the pressure of inert gas (Ar) was 20 Torr.

The grown 6H boule of SiC crystal 112 weighed 380 grams. The weight of the polycrystalline SiC deposit 134 formed inside vapor-absorbing member 117″ was about 35 grams. Upon inspection, no inclusions were detected in the boule bulk. The micropipe density in this boule was below 0.3 cm⁻² and the dislocation density was about 9·10³ cm⁻².

The boule of SiC crystal 112 was fabricated into 23 standard 100 mm diameter, 400 microns thick wafers. The resistivity of all wafers was close to 1·10¹¹ Ohm-cm, with the standard deviation below 10%.

As can be seen, sublimation growth of SiC single crystals in accordance with the present invention yields SiC boules with reduced densities of inclusions, such as foreign polytypes, silicon droplets and carbon particles. The invention also leads to reduced densities of micropipes and dislocations.

The invention has been described with reference to exemplary embodiments. Obvious modifications and alterations will occur to others upon reading and understanding the preceding detailed description. It is intended that the invention be construed as including all such modifications and alterations insofar as they come within the scope of the appended claims or the equivalents thereof.

The invention claimed is:

1. An apparatus for sublimation growth of a SiC single crystal comprising:
a growth crucible operative for receiving a source material and a seed crystal in spaced relation and for substantially preventing the escape of vapor produced during sublimation growth of a SiC single crystal on the seed crystal from inside said growth crucible; and
a baffle disposed around the seed crystal in the growth crucible, said baffle defining on a first side thereof in said growth crucible a growth zone where the SiC single crystal grows on the seed crystal, said baffle defining on a second side thereof in said growth crucible a vapor-capture trap around the seed crystal.

2. The apparatus of claim 1, wherein, for substantially preventing the escape of vapor produced during sublimation growth of a SiC single crystal on the seed crystal, said growth crucible:
is made from a material that is substantially impermeable to the passage of the vapor produced during sublimation growth of a SiC single crystal on the seed crystal; and
includes no intentional pathways or holes for escape of the vapor produced during sublimation growth of a SiC single crystal on the seed crystal from inside the growth crucible to outside the growth crucible.

3. The apparatus of claim 1, wherein the vapor-capture trap is located at a position in the growth crucible where the temperature is lower than that of the seed crystal during the growth of the SiC single crystal on the seed crystal.

4. The apparatus of claim 1, further including a vapor-absorbing member disposed in the vapor-capture trap and operative for absorbing vapor produced during sublimation growth of the SiC single crystal on the seed crystal.

5. The apparatus of claim 4, wherein the vapor-absorbing member is disposed in the vapor-capture trap at a position where the vapor-absorbing member is at a temperature lower than that of the seed crystal during the growth of the SiC single crystal on the seed crystal.

6. The apparatus of claim 5, wherein the temperature of the vapor-absorbing member during the growth of the SiC single crystal on the seed crystal is lower than the temperature of the seed crystal by 3° C. to 20° C.

7. The apparatus of claim 4, wherein the vapor-absorbing member is made from porous graphite having a density between 0.8 and 1.6 g/cm³; a porosity between 30% and 60%; and pore sizes between 1 and 100 microns.

8. The apparatus of claim 1, wherein the baffle defines a pathway inside said growth crucible for the vapor to flow into the vapor-capture trap.

9. The apparatus of claim 8, wherein the growth crucible includes therein a pedestal for supporting the seed crystal intermediate a top of the growth crucible and the source material.

10. The apparatus of claim 9, wherein the pedestal has a height between 5 mm and 25 mm.

11. The apparatus of claim 8, wherein the pathway comprises a gap between an inner diameter of the baffle and an outer diameter of the pedestal.

12. The apparatus of claim 11, wherein the gap is between 1 mm and 8 mm wide.

13. The apparatus of claim 8, wherein the pathway comprises one or more holes in the baffle.

14. A method of SiC sublimation crystal growth comprising:
(a) providing a growth crucible charged with a source material and a seed crystal in spaced relation and a baffle disposed in the growth crucible around the seed crystal, said baffle defining on a first side thereof a growth zone where a single crystal grows on the seed crystal, said baffle defining on a second side thereof a vapor-capture trap around the seed crystal; and
(b) heating the growth crucible of step (a) to a growth temperature whereupon a temperature gradient forms in the growth chamber that causes the source material to sublimate and form a vapor which is transported by the temperature gradient to the growth zone of the growth crucible where the single crystal grows by precipitation of the vapor on the seed crystal, wherein a fraction of the vapor enters the vapor-capture trap.

15. The method of claim 14, wherein the vapor entering the vapor-capture trap forms a deposit therein.

16. The method of claim 14, wherein one or more of the source material, the seed crystal and the single crystal are SiC.

17. The method of claim 14, wherein the vapor-capture trap is located at a position in the growth crucible where the temperature is lower than that of the seed crystal during the growth of the single crystal on the seed crystal.

18. The method of claim 14, further including a vapor-absorbing member inside the vapor-capture trap, wherein the vapor entering the vapor-capture trap is removed during growth of the crystal from the growth zone by chemically reacting with the vapor-absorbing member to form a deposit therein.

19. The method of claim 18, wherein the vapor-absorbing member is at a lower temperature than the seed crystal during growth of the single crystal.

20. The method of claim 18, wherein the vapor-absorbing member is made from porous graphite with a density between 0.8 and 1.6 g/cm³; a porosity between 30% and 60%; and pore sizes between 1 and 100 microns.

21. The method of claim 18, wherein the weight of the deposit is between 5% and 20% of the weight of the grown crystal.

22. The method of claim 14, wherein said baffle defines a pathway for the vapor to flow to the vapor-capture trap.

23. The method of claim 22, wherein:
the growth crucible of step (a) further includes a pedestal for supporting the seed crystal intermediate a top of the growth crucible and the source material; and
the pathway comprises a gap formed between an inner diameter of the baffle and an outer diameter of the pedestal.

24. The method of claim 22, wherein the pathway comprises at least one perforation in a wall of the baffle.
